(19) United States
(12) Patent Application Publication
(10) Pub. No.: US 2008/0272796 A1
(43) Pub. Date: Nov. 6, 2008

(54) PROBE ASSEMBLY

(75) Inventor: Nobuyuki Yamaguchi, Aomori (JP)

Correspondence Address: BRUCE A. JAGGER, 6100 CENTER DRIVE, SUITE 630, LOS ANGELES, CA, 90045, US

(73) Assignee: Kabushiki Kaisha Nihon Micronics

(21) Appl. No.: 12/101,798

(22) Filed: Apr. 11, 2008

(30) Foreign Application Priority Data
May 2, 2007 (JP) 2007-121524

(51) Int. Cl. G01R 1/073

(52) U.S. Cl. 324/762

(57) ABSTRACT

The probe assembly according to the present invention comprises a probe board and a plurality of probes. Each probe has an arm portion extending from the probe board at a distance and substantially along the probe board, a tip portion provided in the arm portion and projecting in a direction away from the probe board, and the tips provided in the tip portions are supported on the probe board at their base ends so as to be arranged in a matrix state on an imaginary XY plane along the X-axis and Y-axis. The respective probes are arranged so that the extending directions of said arms are arranged angularly relative to the X-axis and Y-axis and parallel to one another as seen on a plane P parallel to the imaginary plane.

### RELATED APPLICATIONS

This application claims the benefit of Japanese Patent Application No. 2007-121524, filed May 2, 2007.

### TECHNICAL FIELD

The present invention relates to a probe assembly suitable for use in an electrical test of a flat plate-like device under test such as an integrated circuit chip.

### BACKGROUND

Semiconductor integrated circuits are collectively formed in general so as to be arranged in a matrix state on a semiconductor wafer. Before being separated into each chip, these semiconductor integrated circuits are connected to a tester through an electrical connecting apparatus such as a probe assembly and undergo an electrical inspection by the tester.

In such an electrical inspection, when a plurality of electrodes are arranged in a matrix state in each chip area of a semiconductor wafer, a probe assembly with perpendicular probes is used so that the probes of the probe assembly can contact the corresponding electrodes without interfering with each other (see, e.g., Patent Document 1).

However, after forming a attaching portion for attaching such multiple perpendicular probes to a probe board, it is necessary to attach the perpendicular probe to each attaching portion perpendicularly, and it is feared that such multiple perpendicular probes might easily interfere each other by deformation caused when their tips are pressed against the opposing electrodes.

Also, in a semiconductor apparatus in which rectangular light-receiving element areas are arranged in a matrix state, a method of arranging the probes whose front ends can contact inspection pads aligned along each side of element areas in a diagonal direction angularly to each side of the rectangular element area (see, e.g., Patent Document 2). According to this inspection method, it is possible to bring each probe tip into contact with the inspection pad in a plurality of light-receiving element areas, thereby enabling an electrical inspection of a plurality of light-receiving element area.
[Patent Document 1] Japanese Patent Appln. Public Disclosure No. 8-304460
[Patent Document 2] Japanese Patent Appln. Public Disclosure No. 2006-179813

### BRIEF SUMMARY

An object of the present invention is to provide a probe assembly suitable for use in an electrical inspection of an integrated circuit having electrodes arranged in a matrix state in relatively high density by arranging probes angularly on each side of a rectangular or square element area.

The probe assembly according to the present invention comprises: a probe board, and a plurality of probes each of which has an arm portion extending substantially along the probe board at a distance from the probe board and a tip portion provided at the arm portion and projecting from the probe board in a direction to be away therefrom, the plural probes being supported at the base ends on the probe board such that the tips provided at the tip portions are arranged in a matrix state on an imaginary XY plane along the X- and Y-axes; and it is characterized that the probes are arranged so that the extending directions of the arm portions may be angular relative to the X-axis and Y-axis and in parallel to one another as seen on a plane parallel to the imaginary plane.

In the probe assembly according to the present invention, the probes can be arranged without interference of their arms, because the arm portions of the respective probes are arranged angularly relative to the X- and Y-axes and mutually parallel to one another in a matrix state as seen on a plane parallel to the XY plane where the tips are arranged in the matrix state. Also, the present invention enables to measure or inspect a device under test with high accuracy, since it is possible to assure a length dimension enough to absorb irregularity in height positions of the respective tips or in height dimensions of pads or electrodes of the device under test which the tips abut.

An attaching portion for attaching the arm portion to the probe board can be provided in the probe for mounting the attaching portion at its attaching end on the probe board. Thus, the arm portion can be combined with the probe board so as to extend laterally from the attaching portion. In such a case, the tip portion extends vertically from the arm portion integrally therewith, and the tip is provided at its front end.

The probes can be grouped in correspondence to mutually adjoining plural rectangular areas. The tips of the probes of each group are arranged in a matrix state at each of the rectangular areas, and the directions from the tip portions of the probes toward the base portions of the arm portions in the respective groups are different from group to group. Such an arrangement enables to inspect four devices under test or areas under test disposed to align in four directions, that is, upward, downward, rightward and leftward on one plane, for example, simultaneously and collectively, thereby realizing an efficient inspection.

According to the present invention, as described above, the probes are arranged so that the extending directions of the arm portions may be angular relative to said X-axis and Y-axis and in parallel to one another, as seen on a plane parallel to the imaginary plane, so that an effective length necessary for the arm portions can be set without making the arm portions of the probes interfere with each other. Thus, an electrical inspection of the device under test in which the electrodes are arranged in a matrix state with relatively high density is adequately conducted.

### BRIEF DESCRIPTION OF THE DRAWINGS

FIG. 1 is a bottom view showing an embodiment of the probe assembly according to the present invention.

FIG. 2 is an enlarged sectional view showing the section along the line II-II in FIG. 1.

FIG. 3 is a front view typically showing one of a plurality of probes attached to the probe board of the probe assembly shown in FIGS. 1 and 2.

FIG. 4 is a plan view of the probe shown in FIG. 3.

FIG. 5 is a plan view showing an arrangement example (No. 1) of the probes of the probe assembly according to the present invention by transmitting the probe board from the side of the probe board.

FIG. 6 is a plan view showing an arrangement example (No. 2) of the probes of the probe assembly according to the present invention by transmitting the probe board from the side of the probe board.

FIG. 7 is a plan view showing an arrangement example (No. 3) of the probes of the probe assembly according to the present invention by transmitting the probe board from the side of the probe board.

FIG. 8 is a plan view showing an arrangement example (No. 4) of the probes of the probe assembly according to the present invention by transmitting the probe board from the side of the probe board.

### DETAILED DESCRIPTION

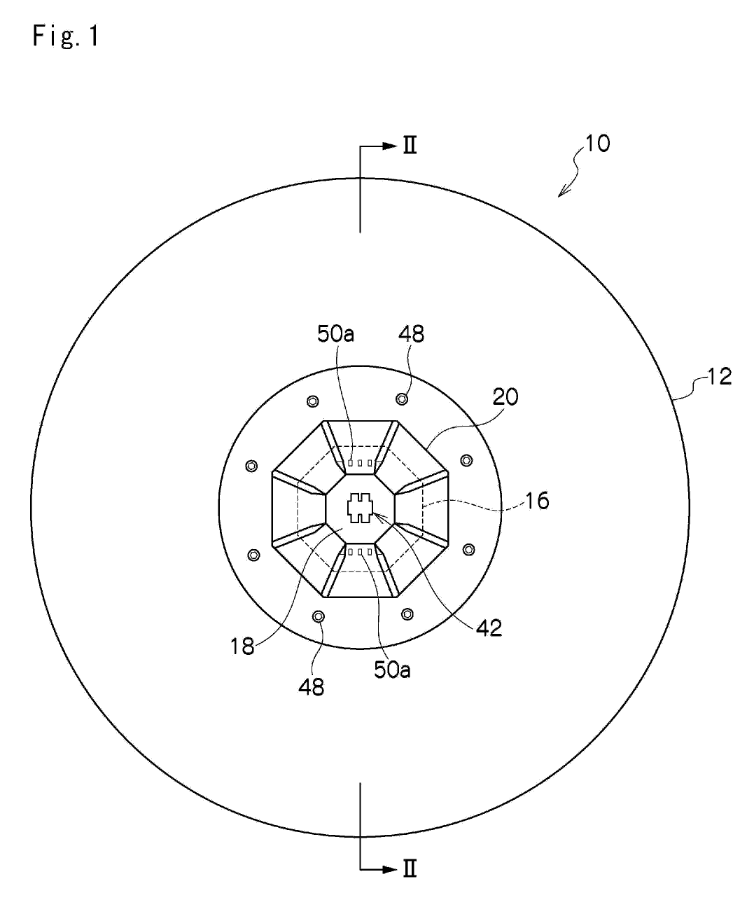

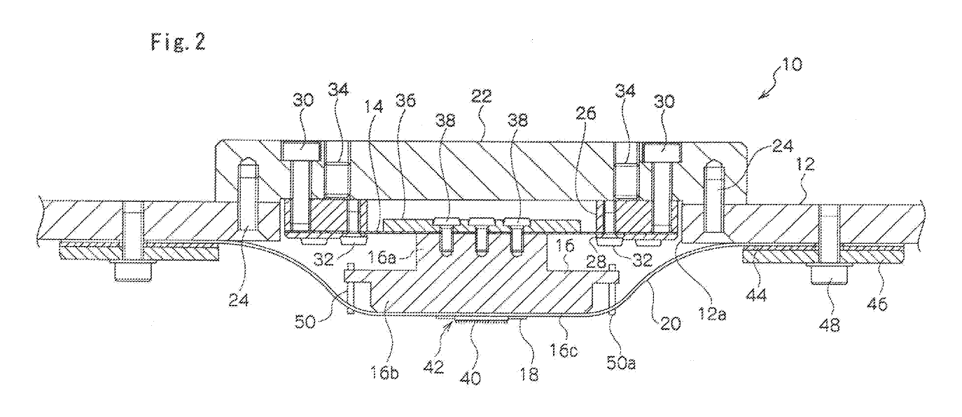

As shown in FIGS. 1 and 2, the probe assembly 10 according to the present invention comprises: a rigid wiring board 12; a block 16 elastically supported on the rigid wiring board through a spring member (see FIG. 2); and a probe sheet 20 in which a probe board 18 with a plurality of conventionally well known conductive paths to be electrically connected respectively to not shown plural conductive paths within the rigid wiring board 12 is integrally formed. In this embodiment, the probe board 18 is formed at the central portion of the flexible probe sheet 20.

Within the rigid wiring board 12, a wiring path to be connected to an electric circuit of a tester body is formed as is conventionally well known, and the rigid wiring board 12 has a circular opening 12a at its center. On the upper surface of the rigid wiring board 12, as shown in FIG. 2, is disposed a circular support plate 22 made of a metal such as, for example, stainless steel, covering the circular opening 12a. The support plate is secured to the rigid wiring board 12 through a bolt 24 screwed into the support plate. The support plate 22 serves to support the rigid wiring board 12 and reinforce the rigid wiring board.

The spring member 14 is made of a flat plate-like spring material and is held within a circular opening 12a of the rigid wiring board 12 across the opening through an annular attaching plate 26 sandwiching the annular outer edge portion of the spring member 14 from both surfaces and through an annular retainer plate 28. To hold this spring member 14, the attaching plate 26 is combined with the underside of the support plate 22 with a bolt 30, and the retainer plate 28 is combined with the attaching plate 26 with a bolt 32 screwed into the mounting plate 26 extending through the retainer plate and the annular outer edge portion of the spring member 14.

In the embodiment shown in FIG. 2, a parallel adjustment screw member 34 for adjusting the holding attitude of the spring member 14 with the bolt 30 relaxed is screwed into the support plate 22 so that its front end can abut the top surface of the mounting plate 26.

The above-mentioned block 16 is secured to the spring member 14 held within the circular opening 12a of the rigid wiring board 12. The block 16 includes a stem portion 16a having a rectangular cross section, and a support portion 16b having a right octagonal cross sectional shape continued on the lower end of the stem portion.

The block 16 is combined with the spring member 14 on the top surface of the stem portion 16a with a flat underside 16c of the support portion directed downward. For this combination, a fixing plate 36 sandwiching the spring member 14 together with the stem portion 16a is secured to the stem portion 16a with a screw member 38 to be screwed into the step portion 16a.

The probe board 18 in the central portion of the probe sheet 20, in the example shown in FIG. 1, is an octagonal part formed to correspond to the underside 16c (see FIG. 2) of the block 16. In the central portion of the probe board 18 corresponding to the underside 16c of the block 16 is formed a contact area 42 where multiple probes 40 (see FIG. 2) are provided collectively. The respective probes 40 are connected to the corresponding conductive paths within the probe board 18 and formed to project from the underside of the contact area 42, i.e., from the opposite side surface of the surface opposing the underside 16c of the block 16.

The probe sheet 20, as shown in FIG. 2, is adhered to the underside 16c of the block 16 so that the contact area 42 of the probe board 18 can be supported on the underside 16c through an adhesive. Also, at the outer edge portion, the probe sheet 20 is combined with the rigid wiring board 12 such that the part, i.e., the octagonal part, extending outward from the probe board 18 has a slight looseness.

For the combination with the outer edge portion of the probe sheet 20, an elastic rubber ring 44 is disposed along the outer edge portion of the probe sheet 20, and a ring fitting 46 covering the elastic rubber ring 44 is disposed. The outer edge portion of the probe sheet 20 is to be combined by tightening of the screw member 48 which penetrates the outer edge portion of the probe sheet 20 and both members 44, 46, and to be screwed into the rigid wiring board 12.

Thus, each probe 40 is connected to the tester body through the conductive path of the probe sheet 20.

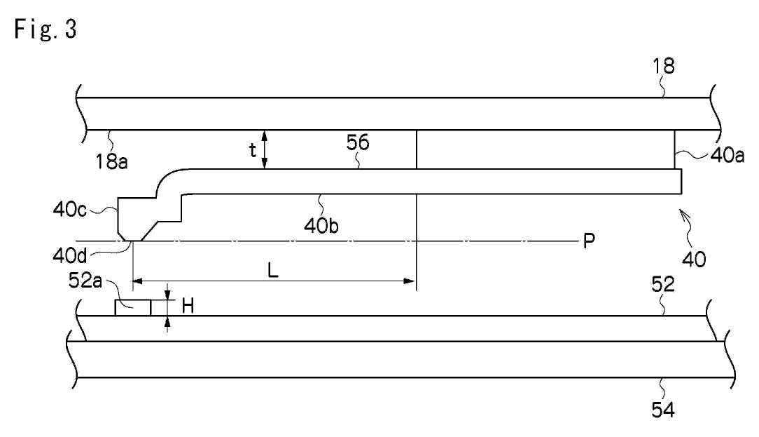

An alignment pin 50 is disposed, if necessary, so as to penetrate the probe sheet 20. At the lower end of the alignment pin 50 is provided an alignment mark 50a which can be photographed from a camera (not shown) supported on a table 54 (see FIG. 3) on which a semiconductor wafer 52 (see FIG. 3) as a device under test is held.

FIG. 3 is a front elevation which representatively shows one of the probes 40 provided on the probe board 18. Each probe 40 is made of a conductive material. This probe 40 is connected to the above-mentioned conductive path corresponding to each probe 40 within the probe board 18, and comprises an attaching portion 40a extending downward from the flat underside 18a of the probe board 18, an arm portion 40b combined with the probe board 18 through the attaching portion, and a tip portion 40c provided at the front end of the arm portion. The arm portion 40b extends along the underside 18a of the probe board 18 laterally from the lower end of the attaching portion 40a. The front end of the arm portion 40b is bent downward to be away from the probe board. The tip portion 40c extends from the front end of the arm portion 40b in a direction to be away from the probe board 18, and a tip 40d is formed at its extended end so as to project in a direction to be away from the underside 18a of the probe board 18.

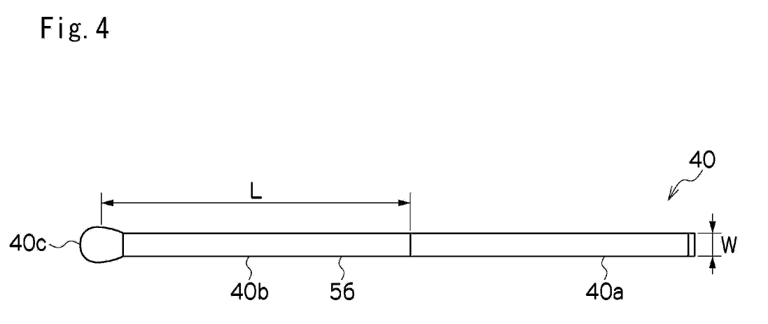

The arm portion 40b has, for example, a rectangular cross section, and, as shown in FIG. 4, has a uniform width dimension W. Referring to FIG. 3 again, when the probe 40 is under no load, its arm portion 40b is held in parallel to the probe board 18. Thus, a flat rear surfaces 56 of the arm portions 40b opposing the flat underside 18a of the probe board 18 are arranged over the longitudinal direction of the arm portions at equal intervals t except the bend portions of the front ends. Also, the tips 40d of all the probes 40 on the probe board 18 are aligned on an imaginary plane P.

As shown in FIG. 3, the probe assembly 10 is positioned such that the tips 40d of the probes provided on the probe board 18 correspond to the electrodes 52a of the semiconductor wafer 52 which is the device under test disposed on the table 54. Then, when a table 54 moves so that the probe assembly 10 and the table 54 may approach each other, the tips 40d of the respective probes 40 abut the corresponding electrodes 52a. When the tips 40d of the probes 40 are subjected to pressing force by subsequent movement of the probe assembly 10, the overdrive force causes the arm portions 40b of the probes 40 an arc-like elastic deformation such that the tip portions 40c formed at the front end of the arm portions 40b approach the underside 18a of the probe assembly 10. The effective length L of the arm portion 40b of the probe 40 under the elastic deformation becomes a length from the central point of the tip 40d up to the attaching portion 40a.

The height positions of the tips 40d of the respective probes 40 provided on the probe board 18 and the height dimensions H of the corresponding electrodes 52a vary within allowable errors at the time of production. When the above-mentioned overdrive force acts, the effective length L of the arm portion 40b is set relative to the rigidity of the arm portion, irrespective of these allowable errors, so that the tips 40d of all the probes 40 on the probe board 18 can give a displacement enough to contact the corresponding electrodes 52a properly.

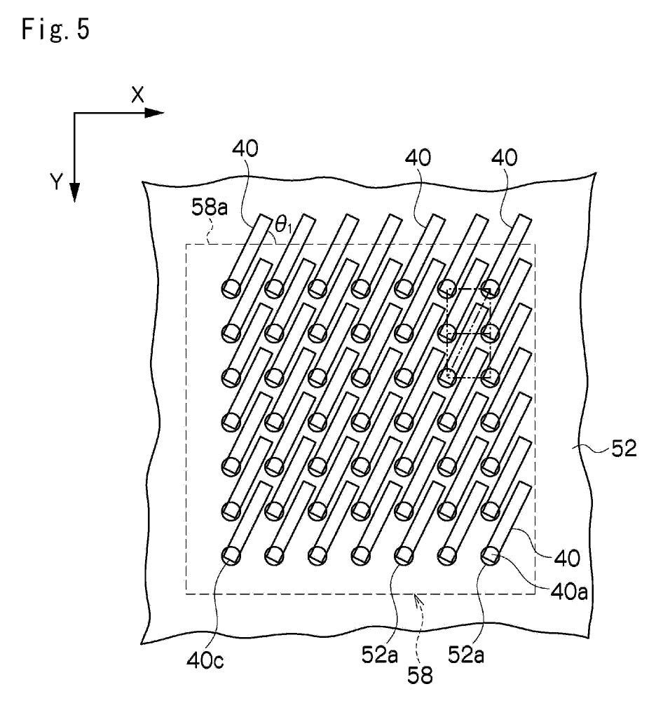

FIG. 5 shows an example of arrangement of the probes 40 having such an effective length L as a perspective view when seeing the semiconductor wafer 52 by transmitting the probe board from the probe board 18. In the rectangular chip areas 58 of the semiconductor wafer 52 are aligned a plurality of electrodes 52a along each side of the rectangular chip areas in a matrix state, namely, in a grid-like arrangement.

Also, the contact areas 42 of the probe board 18 are provided with the probes 40 corresponding to the electrodes 52a within the rectangular chip area 58. These probes 40 are secured to the probe board 18 at each attaching portion 40a so that the tips 40d can correspond to the respective electrodes 52a on the plane P. Therefore, as seen on the plane P, the respective tips 40d are arranged along the grids parallel to the X- and Y-axes on the plane. The respective arm portions 40b are arranged parallel to one another so as to be angular to each side of the grids, for example, to form an angle θ1 with respect to the X-axis when seen on the imaginary plane P.

In the example shown in FIG. 5, the probes are arranged on the probe board 18 such that the X-axis on the imaginary plane P coincides with one side 58a of the rectangular chip area 58. Also, the probes 40 are arranged along two directions of the diagonals of the grids continued in the Y-axis direction, and the respective probes 40 are disposed angularly (θ1 ≠90° and 180°) such that the longitudinal direction of their arm portions 40b and one side 58a of the rectangular chip area 58 form the angle θ1.

Therefore, irrespective of the variations in the height positions of the electrodes 52a and the height positions of the tips 40d within an allowable errors, the effective length of the arm portion 40b can be set so that a proper needle pressure can be obtained on the probes 40.

On the other hand, when the probes 40 are arranged to coincide with the X-axial direction or the Y-axial direction on the plane P, the length of the arm portion is limited to the length of one side or less of one of the grids.

According to the present invention, in the example shown in FIG. 5, the length of the arm portion 40b of the probe 40 can be set longer than the length of one side of the one grid; therefore, irrespective of the allowable error, the actual effective length L of the arm portion 40b can be set to enable each probe 40 to be pressed against the corresponding electrode 52a with a proper stylus pressure, thereby enabling to measure or inspect a device under test at a high accuracy.

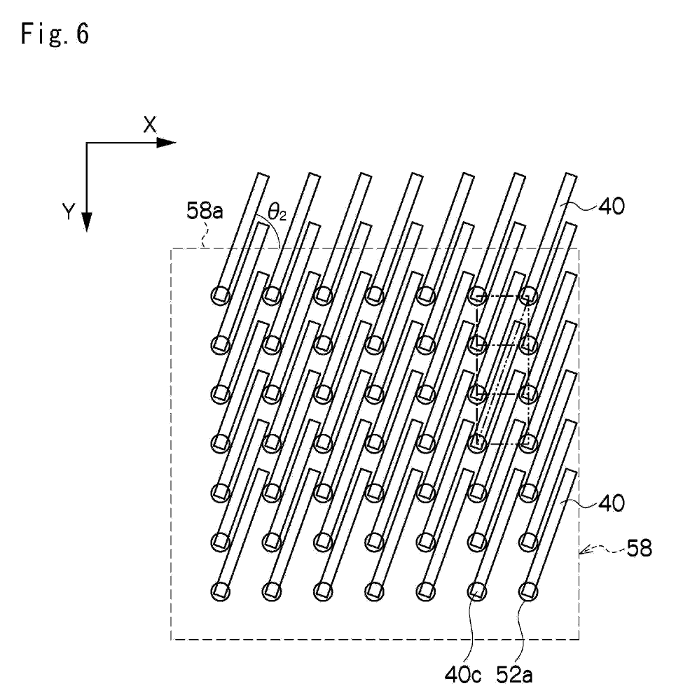

FIG. 6 shows an example wherein the arm portions 40b of the probes 50 are arranged along the diagonals of the three grids continuous in Y-axial direction. In this example, the respective probes 40 are arranged to be parallel to one another so that the length direction of the arm portion 40b and one side 58a of the rectangular chip area 58 may form a larger angle θ2 larger than the angle θ1. In view of this, in the example shown in FIG. 6, the length dimension of the arm portion 40b can be made larger than that of the example shown in FIG. 5. Consequently, for setting the stylus pressure at a desired value, the degree of freedom is increased over the example shown in FIG. 5.

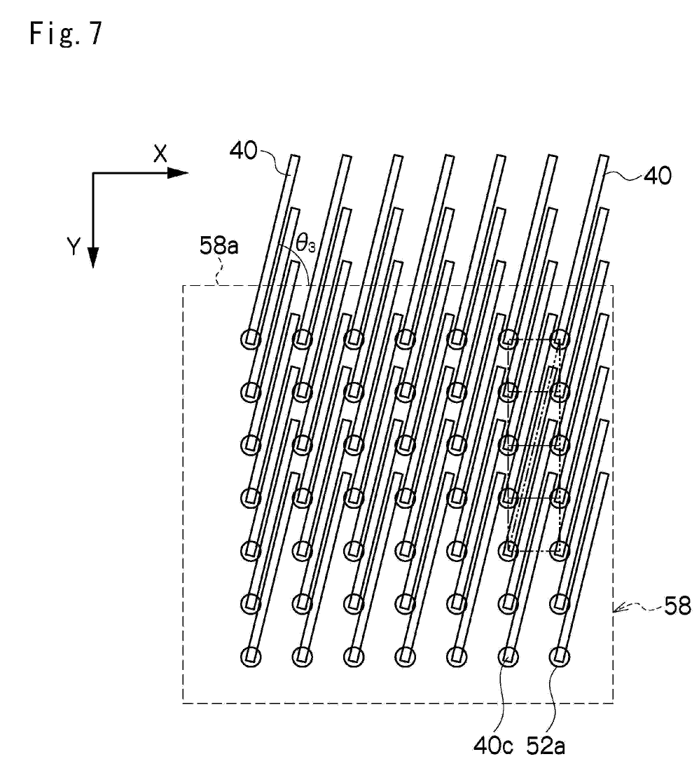

Further, FIG. 7 shows an example wherein the arm portions 40b of the probes 40 are arranged along the diagonals of the four grids continued in the Y-axial direction. In this example, the respective probes 40 are arranged in parallel to one another so that the length direction of the arm portions 40b and one side 58a of the rectangular chip areas 58 may form the angle θ3 larger than the angle θ2. In view of this, the example shown in FIG. 7 can make the length direction of the arm portion 40b larger than the example shown in FIGS. 5 and 6; therefore, the length of the arm portion 40b can be made largest of the three examples. Consequently, in setting the stylus pressure at a desired value, the degree of freedom is increased over the example shown in FIG. 6.

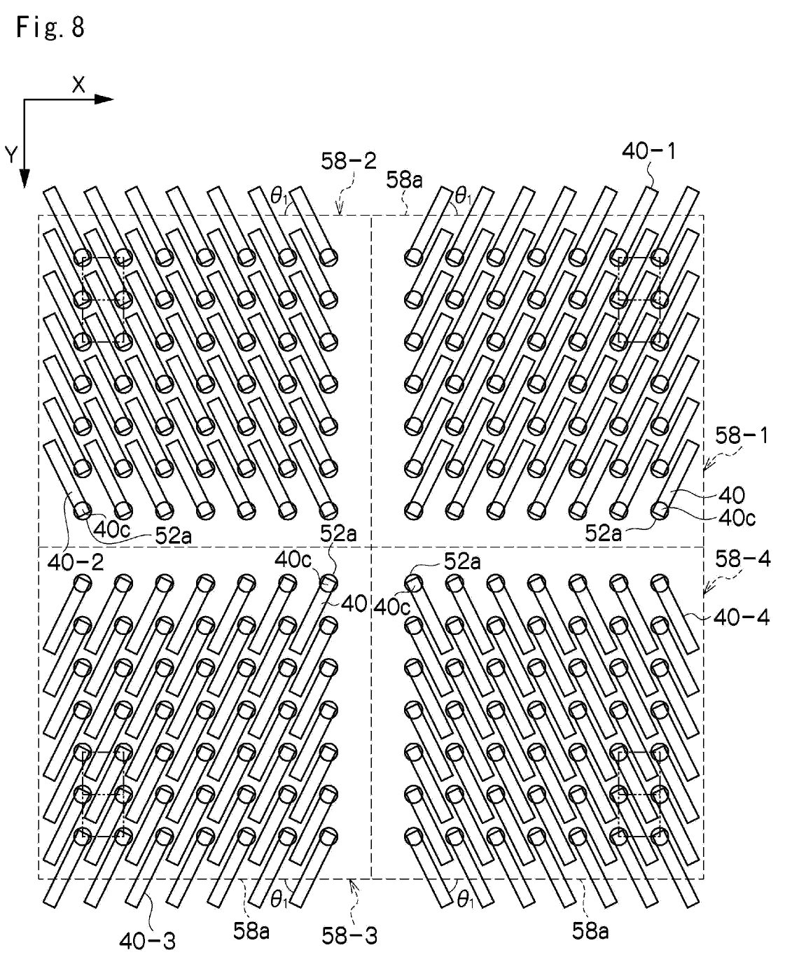

In the example shown in FIG. 8, four rectangular chip areas 58 (58-1 to 4) in all are formed in the vertical and lateral directions in FIG. 8, and the probes 40 corresponding to the respective areas 58 are grouped into four groups.

The probes 40-1 of the group corresponding to the rectangular chip area 58-1 located right above in the Figure are arranged along the diagonals of the two grids. The direction of the probes 40-1 becomes upper right so that a direction seen from the tip portion 40c toward the attaching portion 40a (base portion) may form an angle θ1 to a side 58a. Also, the arm portions 40b of the probes 40-2 of the group corresponding to the rectangular chip area 58-2 located upper leftward are likewise arranged along the diagonals of the two of the grids, while the probes 40-2 are arranged upper leftward so that the direction seen from the tip portions 40c toward the attaching portions 40a (base portions) may form an angle (180°−θ1).

While the arm portions 40b of the probes 40-3 of the group which corresponds to the rectangular chip area 58-3 located lower leftward are likewise arranged along the diagonals of the two grids, the probes 40-3 are arranged lower leftward so that the direction seen from the tip portions 40c toward the attaching portions 40a (base portions) may form an angle (180°−θ1).

Thus, the arm portions 40b of the probes 40 (40-1 to 4) corresponding to the adjoining four rectangular chip areas 58-1 to 4 are arranged in different directions so that the respective arm portions 40b may be arranged radially. Consequently, the probes 40 can be arranged to correspond to the electrodes 52a disposed in a matrix state without mutually interfering among the respective groups. As a result, it is possible to test simultaneously and collectively the four rectangular chip areas 58-1 to 4 in which the electrodes 52a are disposed in a matrix state at high density, thereby enabling an efficient inspection.

According to the present invention, as mentioned above, the effective length L of the arm portion 40b of the probe 40 can be set relatively long, so that its degree of freedom increases. It is, therefore, possible to set the effective length L of the arm portion 40b so that the tips 40d of all the probes 40 on the probe board 18 can be given a displacement enough to properly contact the corresponding electrodes 52a. In other words, since the degree of freedom concerning the effective length L of the arm portion 40b of the probe 40 increases, the effective length L can be set so that a proper stylus pressure is obtained on each probe 40 without any change in the width dimension W of the arm portion 40b.

The present invention is not limited to the foregoing embodiments and can be modified variously. For instance, while an example wherein an attaching portion 40a is provided in the arm portion as the base end of the arm portion 40b and the attaching portion is connected to the probe board 18 is shown herein, it is possible, for example, to form a curved portion in the arm portion 40b without providing the attaching portion 40a and to connect the curved portion directly to the probe board 18.

1. A probe assembly comprising: a probe board; and a plurality of probes to be supported at their base ends on said probe board, each probe having an arm portion extending at a distance from said probe board and substantially along said probe board and having a tip portion projecting in a direction to be away from said probe board, tips provided at said tip portions being aligned in a matrix state along an X-axis and a Y-axis on an imaginary XY plane; wherein the respective probes are arranged so that the extending directions of said arm portions may be angular relative to said X-axis and Y-axis and in parallel to one another, when seen on a plane parallel to said imaginary plane.

2. The probe assembly claimed in claim 1, wherein each of said probes further has an attaching portion for attaching said arm portion to said probe board, said attaching portion being attached to said probe board at its attaching end, and said arm portion extending laterally from said attaching portion, wherein said tip portion having said tip provided at it front end extends vertically from said arm portion integrally therewith.

3. A probe assembly as claimed in claim 1, wherein said probes are grouped respectively in to correspondence to a plurality of rectangular areas adjacent to one another, wherein the tips of said probes in each group are arranged in a matrix state in each of said rectangular area, and wherein directions from said tip portions to the base portions of said arm portions differ according to the groups of said probes.
